(19) United States
(12) Patent Application Publication
(10) Pub. No.: US 2024/0124717 A1
(43) Pub. Date: Apr. 18, 2024

(54) COMPONENTS PROTECTION LAYER

(71) Applicant: HONEYWELL INTERNATIONAL INC., Charlotte, NC (US)

(72) Inventors: Sandeep MAUT, Charlotte, NC (US); Vijayakumar S, Charlotte, NC (US); Nikhil P.S., Charlotte, NC (US)

(21) Appl. No.: 18/475,865

(22) Filed: Sep. 27, 2023

(30) Foreign Application Priority Data
Oct. 13, 2022 (IN) 202211058508

(51) Int. Cl. C09D 5/18; C09D 179/08; C09D 183/06

(52) U.S. Cl. CPC C09D 5/18; C09D 179/08; C09D 183/06; H05K 5/0247

(57) ABSTRACT

Various embodiments are directed to a method for protecting an electronic comprising: depositing a first epoxy resin on the electronic component; curing the first epoxy resin to form a first cured epoxy layer, disposing a polyimide film on the first cured epoxy layer to form a polyimide layer, depositing a second epoxy resin on the polyimide layer, and curing the second epoxy resin to form a second cured epoxy layer. The first cured epoxy layer, the polyimide layer, and the second epoxy layer form a multi-layered protective coating that is configured at least in part to protect the electronic component from at least adverse effects from varying light intensities.

### CROSS-REFERENCE TO RELATED APPLICATIONS

This application claims priority pursuant to 35 U.S.C. 119(a) to Indian Application No. 202211058508, filed Oct. 13, 2022, which application is incorporated herein by reference in its entirety.

### FIELD OF THE INVENTION

Various embodiments described herein relate generally to components protection layer device, and more particularly to components protection layer for protecting electronic components from light and thermal sensitivity.

### BACKGROUND

Several components of a device, particularly electronic components may be sensitive to light and heat, which may adversely affect the performance of these components. For example, electronic components (e.g., piezoresistive pressure sensors, capacitive pressure sensors, temperature sensors, force sensors, and/or the like) are commonly used in various applications and industries, where the performance (e.g., reliability, accuracy, durability, and/or the like) of these electronic components is especially critical. For example, medical facilities (e.g., hospitals, doctor's office, immediate care centers, and/or the like) utilize devices/equipment for diagnosing and treating patients that incorporate sensors for measuring critical parameters of a patient (e.g., sensors for measuring and/or monitoring blood pressure and/or other vitals of a patient). Accordingly, proper functioning of these sensors (as well as many other electronic components) is desired and critical. However, as noted above, these components may be used in environments that could adversely affect their performance. For example, the performance of electronic components that are sensitive to light and/or heat may be adversely affected by changing light intensity and/or temperature when used under such conditions. For example, various sensors (e.g., blood pressure monitoring sensors) used in medical facilities, may be sensitive to light and may be exposed to various light intensities. For example, these sensors may be used in patient rooms that have bright light sources, as well as in patient rooms that have dark, as well as in patient rooms that have dim light sources. These changing light condition may adversely affect the performance of these sensors, and it is generally very difficult, expensive, and often impossible to calibrate a sensor for all possible light intensity that these sensors may be exposed to.

Furthermore, many electronic components go through different assembly processes that may subject them to thermal shock (e.g., reflow process for soldering, and/or the like) and/or mechanical shock (e.g., mounting stress, assembly stress, handling stress, and/or the like) that could result in latent failure, such as diminished and/or improper functioning of the electronic components post assembly

Through applied effort, ingenuity, and innovation, many of these identified problems have been solved by developing solutions that are included in embodiments of the present disclosure, many examples of which are described in detail herein.

### BRIEF SUMMARY

Various embodiments described herein relate to methods for protecting electronic components. Various embodiments are directed to methods for protecting electronic components comprising: depositing a first epoxy resin on the electronic component, curing the first epoxy resin to form a first cured epoxy layer, disposing a polyimide film on the first cured epoxy layer to form a polyimide layer, depositing a second epoxy resin on the polyimide layer, and curing the second epoxy resin to form a second cured epoxy layer, wherein the first cured epoxy layer, the polyimide layer, and the second epoxy layer form a multi-layered protective coating that is configured at least in part to protect the electronic component from at least adverse effects from varying light intensities.

In various embodiments, the multi-layered protective coating is further configured to protect the electronic component from mechanical shock.

In various embodiments, the multi-layered protective coating is further configured to protect the electronic component from thermal shock.

In various embodiments, the first cured epoxy layer comprises a first layer of the multi-layered protective coating, the polyimide layer comprises a second layer of the multi-layered protective coating, and the second epoxy resin comprises a third layer of the multi-layered protective coating.

In various embodiments, the multi-layered protective coating encapsulates the electronic component.

In various embodiments, the electronic component comprises a sensor.

In various embodiments, the first epoxy resin comprises applying ultraviolet (UV) light to the first epoxy resin.

In various embodiments, curing the second epoxy resin comprises applying ultraviolet (UV) light to the second epoxy resin.

In various embodiments, the polyimide film has a thickness of about 0.03 mm.

In various embodiments, the first epoxy resin has a low viscosity.

In various embodiments, the second epoxy resin has a low viscosity.

In various embodiments, the electronic component is coupled to one or more electrical connection members. In various embodiments, the first epoxy resin is deposited on the electronic components and the electrical connection members.

In various embodiments, the method further comprises, prior to disposing the polyimide film on the first cured epoxy layer, forming the polyimide film into a shape that is substantially the same as a shape defined by the electronic component and the electrical connection members coupled to the electronic component.

In various embodiments, the electronic component is disposed on a substrate, and wherein the first cured epoxy layer is in contact with at least a portion of the substrate.

In various embodiments, the first cured epoxy layer comprises a silicon-based epoxy material.

In various embodiments, the second cured epoxy layer comprises a silicon-based epoxy material.

Various embodiments are directed to an electronic component comprising: one or more electrical connection members extending from the electronic component, and a multi-layered protective coating formed on the electronic component and the one or more electrical connection members, wherein the multi-layered protective coating is configured at least in part to protect the electronic component and the one or more electrical connection members from at least adverse effects from varying light intensities, and wherein the multi-layered protective coating comprises a polyimide film disposed between a first epoxy layer and a second epoxy layer.

In various embodiments, the multi-layered protective coating is further configured to protect the electronic component from mechanical shock.

In various embodiments, the multi-layered protective coating is further configured to protect the electronic component from thermal shock.

In various embodiments, the electronic component is a sensor.

### BRIEF DESCRIPTION OF THE DRAWINGS

Reference will now be made to the accompanying drawings, which are not necessarily drawn to scale, and wherein:

FIG. 1 schematically illustrates an exemplary electronic component with an exemplary multi-layered protective coating in accordance with various embodiments described herein.

FIG. 2A schematically illustrates an exemplary electronic component without a multi-layered protective coating in accordance with various embodiments described herein.

FIG. 2B schematically illustrates an exemplary electronic component with a first layer of an exemplary multi-layered protective coating in accordance with various embodiments described herein.

FIG. 2C schematically illustrates an exemplary electronic component with a first layer and a second layer of an exemplary multi-layered protective coating in accordance with various embodiments described herein.

FIG. 2D schematically illustrates an exemplary electronic component with a first layer, a second layer, and a third layer of an exemplary multi-layered protective coating in accordance with various embodiments described herein.

FIG. 3 provides an example process flow chart for forming a multi-layered protective coating on an electronic component in accordance with various embodiments described herein.

### DETAILED DESCRIPTION

The present disclosure more fully describes various embodiments with reference to the accompanying drawings. It should be understood that some, but not all embodiments are shown and described herein. Indeed, the embodiments may take many different forms, and accordingly this disclosure should not be construed as limited to the embodiments set forth herein. Rather, these embodiments are provided so that this disclosure will satisfy applicable legal requirements. Like numbers refer to like elements throughout.

It should be understood at the outset that although illustrative implementations of one or more aspects are illustrated below, the disclosed systems, and methods may be implemented using any number of techniques, whether currently known or not yet in existence. The disclosure should in no way be limited to the illustrative implementations, drawings, and techniques illustrated below, but may be modified within the scope of the appended claims along with their full scope of equivalents. While values for dimensions of various elements are disclosed, the drawings may not be to scale.

The words “example,” or “exemplary,” when used herein, are intended to mean “serving as an example, instance, or illustration.” Any implementation described herein as an “example” or “exemplary embodiment” is not necessarily preferred or advantageous over other implementations.

Further, while certain embodiments described herein are described with reference to multi-layered protection coating for sensor components and/or other electronic components, it should be understood that the disclosed concepts can be applied to other types of components (e.g., other components that may be sensitive to light, sensitive to heat, subject to thermal shock, subject to mechanical shock, and/or other adverse effects).

Described herein are example devices, systems, and methods for protecting components (e.g., electronic components), such as components of a device. In various embodiments, an exemplary electronic component may be exposed to different environmental conditions, including varying light intensities, varying temperatures, and/or the like, that could adversely affect the performance of the electronic component. Moreover, an exemplary electronic component may go through different assembly processes and may be subject to thermal shocks and/or mechanical shocks, which may result in latent failure of these electronic component post assembly. An example of an electronic component that may be subjected to the noted adverse conditions as described above may be a sensor component wherein the sensor component may be sensitive to light and or heat and may be used in different environmental conditions with varying light intensities, varying temperatures, and/or the like, that could adversely affect the performance of the sensor component. Further, a sensor component may be subject to thermal shock, mechanical shock, and/or other adverse conditions during the assembly process of the sensor component and/or sensor device incorporating the sensor component.

An exemplary protective coating according to various embodiments described herein may be formed over an electronic component, wherein the exemplary protective coating may be configured to provide resistance to light and heat with respect to the electronic components. Additionally, an exemplary protective coating according to various embodiments described herein may be configured to protect an electronic component from at least thermal shock and/or mechanical shock, such as thermal shock and/or mechanical shock that may be produced during assembly of the electronic component and/or assembly of the device incorporating the electronic component, such that latent failure of the electronic component due to thermal shock and/or mechanical shock is prevented or at least significantly reduced.

In various embodiments, an exemplary protective coating as described herein is a multi-layered protective coating having properties that enable protection of electronic components from adverse conditions during associated assembly process, as well as during use of the component under various environmental conditions. In various embodiments, the multi-layered protective coating includes at least one layer comprising (e.g., made of material(s)) that possesses properties (e.g., hardness, and/or the like) that enable protection of components encapsulated within the multi-layered protective coating against at least thermal shock and mechanical shock.

Additionally and/or alternatively, in various embodiments, the multi-layered protective coating includes at least one layer comprising (e.g., made of material(s)) that possesses properties (e.g., light resistance, thermal resistance, and/or the like) that provides light resistance and/or heat-resistance with respect to components encapsulated within the multi-layered protective coating, such that poor performance due to exposure to different light intensity (e.g., changing ambient light conditions) is minimized and/or eliminated.

Additionally and/or alternatively, in various embodiments, the multi-layered protective coating includes at least one layer comprising (e.g., made of material(s)) that possesses properties (e.g., viscosity, and/or the like) that enable the multi-layered protective coating to be applied to various electronic components, including electronic components located within an electronic assembly in locations that would otherwise be difficult for many conventional/traditional component protection methods to access (thus, unable to protect).

In various embodiments, the multi-layered protective coating may be applied to an electronic component, such that the multi-layered protective coating encapsulates (e.g., covers) the electronic component. An example of such electronic component is a microelectromechanical systems (MEMS) pressure sensor (e.g., a piezoresistive sensor, a capacitive sensor) which may be used in various applications, including as sensors for monitoring blood pressure and/or other parameters (e.g., vitals) of a patient/individual.

An electronic assembly and/or device may comprise one or more electronic components. In various embodiments, an exemplary multi-layered protective coating may be applied to (e.g., formed over) one or more of the one or more electronic components of an electronic assembly and/or device. For example, where an electronic assembly comprises a plurality of electronic components, in some embodiments, an exemplary multi-layered protective coating as described herein may be applied to (e.g., formed over) a subset of the plurality of electronic components of the electronic assembly, such that the multi-layered protective coating encapsulates each of the electronic components of the subset of the plurality of electronic components (e.g., at least a portion of each of the subset of the plurality of electronic components). In some embodiments, the subset of the plurality of electronic components may comprise components of the device that are sensitive to light intensity, thermal shock, mechanical shock, physical damage, and/or the like. As another example, where an electronic assembly comprises a plurality of electronic components, in some embodiments, an exemplary multi-layered protective coating as described herein may be applied to each component of the plurality of electronic components, such that the multi-layered protective coating encapsulates each of the plurality of electronic components (e.g., at least a portion of each of the plurality of components of the electronic assembly). In the noted examples above, the plurality of electronic components may be mechanically and/or electrically coupled to one another (e.g., directly or indirectly).

In various embodiments, an exemplary protective coating according to various embodiments described herein may be deposited on one or more elements coupled to the component. An example of such one or more elements may include electrical connection members (e.g., electrical wire, electrical leads, and/or the like) coupled to the component. In some embodiments, an electronic component may be coupled to another electronic component and/or to a substrate (such as a printed circuit board) via one or more electrical connection members.

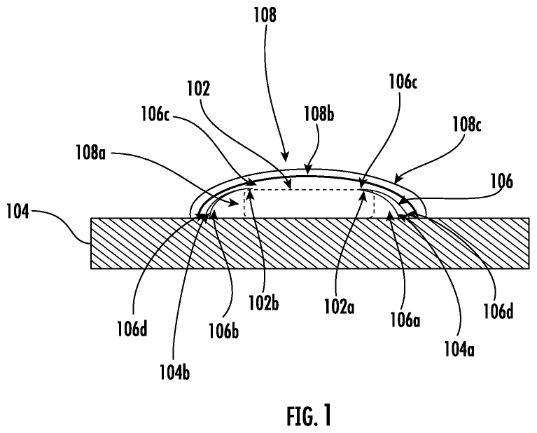

FIG. 1 schematically depicts an exemplary electronic component 102 disposed on a substrate 104. In various embodiments, the substrate 104 may comprise a printed circuit board (PCB). In various embodiments the substrate 104 may be mechanically and/or electrically coupled to the substrate. A non-limiting example of an electronic component 102 may be a sensor component, wherein the sensor component may be mounted on a PCB substrate.

As shown in FIG. 1, the electronic component 102 may be coupled to one or more electrical connection members 106. In some embodiments, the one or more electrical connection members may comprise one or more sets of electrical connection members. For example, the depicted embodiment of FIG. 1 includes two sets of electrical connection members 106a and 106b, each set of electrical connection members 106a, 106b comprising a plurality of electrical connection members extending from the electronic component 102. In various embodiments, the electrical connection members 106 may comprise electrical wires, electrical cables, and/or the like. In various embodiments, the electrical connection members may be mechanically and/or electrically coupled to the substrate 104 and/or other electronic components (e.g., other components disposed on the substrate 104).

In the depicted example embodiment of FIG. 1, each set of electrical connection members 106a, 106b may be mechanically and/or electrically coupled to the electronic component 102, as well as mechanically and/or electrically coupled to the substrate 104. For example, as depicted in FIG. 1, a first electrical connection end 106c of each electrical connection member 106 of the first set of electrical connection members 106a may be coupled (e.g., mechanically and/or electrically) to a first electrical connection portion 102a of the electronic component 102, and a second electrical connection end 106d of each electrical connection member 106 of the first set of electrical connection members 106a may be coupled (e.g., mechanically and/or electrically) to a first electrical connection portion 104a of the substrate 104. As further depicted in the example embodiment of FIG. 1, a first electrical connection end 106c of each electrical connection member 106 of the second set of electrical connection members 106b may be coupled (e.g., mechanically and/or electrically) to a second electrical connection portion 102b of the electronic component 102, and a second electrical connection end 106d of each electrical connection member 106 of the second set of electrical connection members 106b may be coupled (e.g., mechanically and/or electrically) to a second electrical connection portion 104b of the substrate 104. It should be understood that in some embodiments, the electronic component 102 and/or the substrate 104 may not be coupled to an electrical connection member. It should also be understood that while the depicted embodiment of FIG. 1 depicts a single electronic component mounted on the substrate, a plurality of electronic components may be mounted on the substrate 104.

An exemplary multi-layered protective coating 108 may be formed on at least a portion of the electronic component 102. As shown in the depicted embodiment of FIG. 1, an exemplary multi-layered protective coating 108 described herein may be formed over (e.g., applied to) electronic component 102, such that the multi-layered protective coating 108 encapsulates (e.g., covers, encloses) at least a portion of the electronic component 102. For example, in various embodiments, an exemplary multi-layered protective coating 108 may be applied to the electronic component 102, such that the multi-layered protective coating 108 substantially encapsulates (e.g., encapsulates in entirety) the electronic component 102.

Additionally, in various embodiments, the multi-layered protective coating 108 may be formed over the one or more electrical connection members coupled to the electronic component 102. For example, in various embodiments, the multi-layered protective coating 108 may be formed over each electrical connection member coupled to the electronic component 102. As further shown in the depicted embodiment of FIG. 1, an exemplary multi-layered protective coating 108 described herein may be formed over the one or more electrical connection members 106 coupled to the electronic component 102, such that the multi-layered protective coating 108 encapsulates (e.g., covers) at least a portion of the one or more electrical connection members 106. For example, in various embodiments, an exemplary multi-layered protective coating 108 may be formed over/on one or more electrical connection members 106 coupled to the electronic component 102, such that the multi-layered protective coating 108 substantially encapsulates the respective electrical connection member 106. As shown in the illustrated embodiment of FIG. 1, the multi-layered protective coating 108 may be formed over/on a group of electrical connection members (e.g., set of electrical connection members 106a, 106b), such that the multi-layered protective coating 108 encapsulates the group of electrical connection members 106a, 106b. As shown in FIG. 1, the electronic component 102 and the one or more electrical connection members 106 may define a perimeter, where the multi-layered protective coating 108 may encapsulate the electronic component 102 and the one or more electrical connection members 106, such that the multi-layered protective coating 108 spans the perimeter defined by the electronic component 102 and the one or more electrical connection members 106.

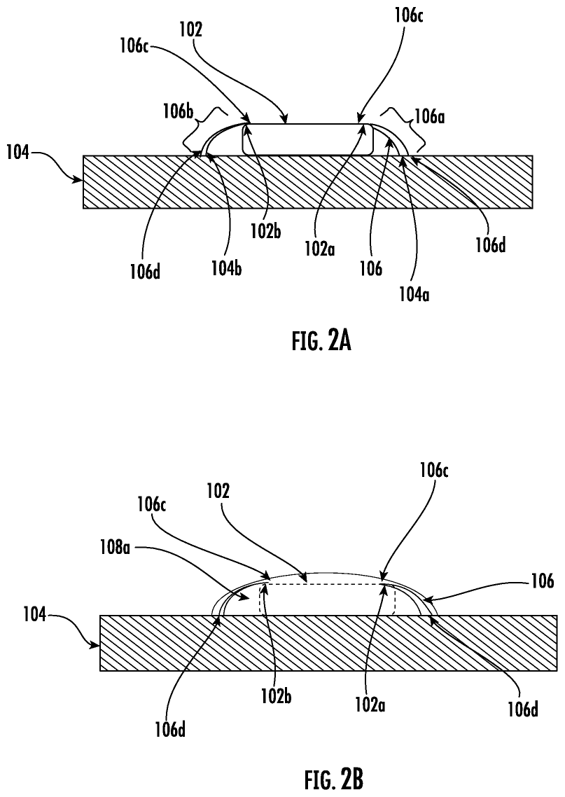

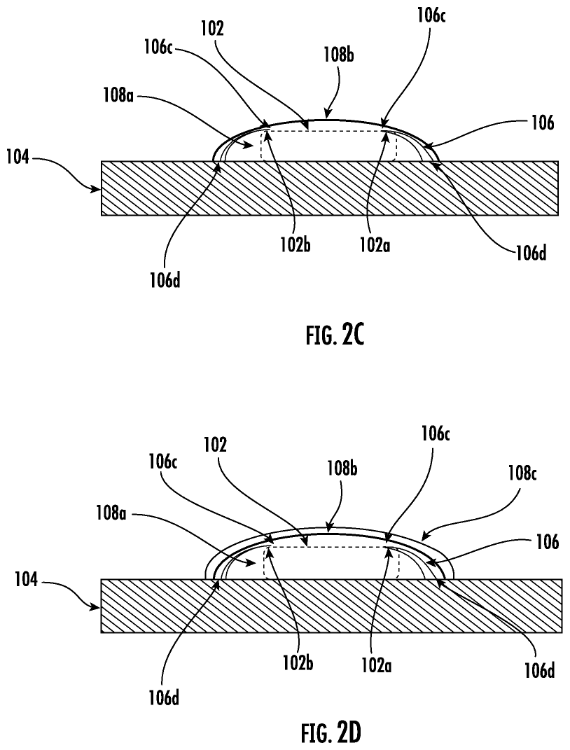

In the depicted embodiment of FIG. 1, the multi-layered protective coating 108 includes a first layer 108a comprising cured epoxy material, a second layer 108b comprising polyimide material (e.g., polyimide film), and a third layer 108c comprising cured epoxy material. In various embodiments, as shown in FIG. 1, the second layer 108b (e.g., polyimide layer) comprising polyimide material may be disposed between the first layer 108a (e.g., first epoxy layer) comprising a first epoxy material and a third layer 108c (e.g., second epoxy layer) comprising a second epoxy material, such that the second layer 108b is in contact with both the first layer 108a and the third layer 108c. As illustrated in FIGS. 2A-2D, in various embodiments, the first layer 108a is formed over/on the electronic component 102 and the electrical connection members 106, the second layer 108b is formed over/on the first layer 108a, and the third layer 108c is formed over/on the second layer 108b.

In various embodiments, each of the first, second, and third layers may have a thickness that may be based at least in part on the application and/or the desired protection. In some embodiments, the first layer 108a comprises a first cured epoxy material. In various embodiments, the first layer 108a may have a preferred thickness between 0.10 mm and 0.90 mm. In various embodiments, the second layer 108b comprises a polyimide material (e.g., polyimide film). In various embodiments, the second layer 108b may have a preferred thickness between 0.10 mm and 0.04 mm. In various embodiments, the second layer 108b comprises a polyimide film having a thickness of about 0.03 mm. In various embodiments, the third layer 108c comprises a second cured epoxy material. In various embodiments, the third layer 108c may have a preferred thickness between 0.10 mm and 0.90 mm.

In various embodiments, the first layer 108a of the multi-layered protective coating may be formed at least in part of an epoxy resin (e.g., a first cured epoxy resin composition), wherein the epoxy resin is cured to form a first layer 108a comprising a first cured epoxy material and wherein the first cured epoxy material may possess one or more desired properties (e.g., suitable heat resistance, chemical resistance, corrosion resistance, mechanical properties, and/or processing properties, such that the first layer 108a in conjunction with the other layers of the multi-layered protective coating 108 may provide sufficient component protection with respect to the electronic component 102 and the electrical connection members coupled to the electronic component (e.g., under adverse operating conditions and assembly processes). As a non-limiting example, the epoxy resin may comprise a Bisphenol A-based epoxy resin. In various embodiments, the first cured epoxy material may comprise an epoxy having a color that is dark (e.g., black, tan, and/or the like) and which may absorb any incident light thereon. Examples of such epoxy include EP1325, EP1325LV, EP1320, EP1320LV, EN525.

Additionally and/or alternatively, the first layer 108a of the multi-layered protective coating may be formed at least in part of an epoxy resin having suitable curing properties (e.g., low viscosity, low curing time, and/or the like). In various embodiments, the first layer 108a is formed at least in part of a low viscosity epoxy resin, wherein the low viscosity epoxy resin may provide flow properties and/or depositing (e.g., dispensing) properties that enable the epoxy resin (and thus the multi-layered protective coating 108) to be evenly and efficiently deposited over/on electronic components that would otherwise be difficult (or impossible) to reach, such as electronic components located in difficult-to-reach areas of complex and/or intricate design circuits.

In various embodiments, a first epoxy resin (e.g., as described above) may be cured using ultraviolet (UV) light/radiation to form the first layer 108a comprising a first cured epoxy layer. For example, the first layer 108a may be formed of a UV-cured epoxy resin, wherein the UV-cured epoxy resin may have low viscosity that provides suitable flow and/or depositing properties. In various embodiments, the first layer 108a may be formed at least in part of two or more epoxy resins have different properties so as to form a first layer 108a comprising a first cured epoxy material having a desired level of protection with respect to the electronic component. In some embodiments the first cured epoxy material may comprise a silicon-based epoxy. For example, in various embodiments the first cured epoxy layer may comprise a silicon-based epoxy material. In various embodiments, the first layer 108a may comprise an epoxy having a viscosity between 36,0000 cP and 400,000 cP. In some embodiments, the first layer 108a may have a color that is substantially black. In some embodiments, the first layer 108a may have a color that is substantially tan. In some embodiments, the first layer 108a may have a high ionic purity (e.g., Cl<50 ppm, K<50 ppm, Na<50 ppm). In some embodiments, the first layer 108a may have a Glass Transition Temperature (Tg) between 80 and 135° C. In some embodiments, the first layer 108a may have a specific Gravity between 1.2 to 1.97. In some embodiments, the first layer 108a may have a hardness between 70 and 90 shore D.

In various embodiments, the second layer 108b of the multi-layered protective coating 108 may be formed at least in part of a polyimide material, wherein the polyimide material may possess properties (e.g., light/radiation resistance, tensile strength/hardness, chemical resistance, thermal/heat resistance, dielectric properties, coefficient of thermal expansion, and/or other properties) at suitable values/ranges, such that the polyimide material in conjunction with the other layers of the multi-layered protective coating 108 may provide sufficient/adequate protection with respect to the electronic component 102, as well as the electrical connection members 106. For example, in various embodiments, the second layer 108b of the multi-layered protective coating may comprise a polyimide film, wherein the polyimide film may possess suitable mechanical, thermal, and optical properties (e.g., high light/radiation resistance) as described below such that an exemplary multi-layered protective coating 108 may provide adequate (e.g., substantial) mechanical, thermal, and optical protection to electronic components and electrical connection members encapsulated within the exemplary multi-layered protective coating 108.

For example, the second layer 108b may be formed of polyimide material having a high light/radiation resistance, such that an exemplary multi-layered protective coating 108 may protect the electronic component 102 and electrical connection members encapsulated within the exemplary multi-layered protective coating 108 from adverse effects due to varying light intensities, thus enabling use of the electronic component 102 and the electrical connection members in adverse conditions. As another example, the polyimide material may have a high thermal/heat resistance and high tensile strength/hardness, such that an exemplary multi-layered protective coating 108 as described herein may protect the exemplary electronic component 102 and electrical connection members 106 encapsulated within the multi-layered protective coating 108 from thermal shock and mechanical shock (e.g., during assembling of the component and/or circuit/electronic component assembly incorporating the component). In some embodiments, the second layer 108b may comprise substantially polyimide material. In some embodiments, the second layer 108b (e.g., polyimide layer/polyimide film) may have a color that is brown (e.g., substantially brown).

In various embodiments, the third layer 108c of the multi-layered protective coating may be formed at least in part of an epoxy resin (e.g., a second cured epoxy resin composition), wherein the epoxy resin may be cured to form a third layer 108c comprising a second cured epoxy material (e.g., second cured epoxy layer), and wherein the third layer comprising the second cured epoxy material may possess one or more desired properties (e.g., suitable heat resistance, chemical resistance, corrosion resistance, mechanical properties, and/or processing properties, such that the third layer 108c in conjunction with the other layers of the multi-layered protective coating may provide sufficient protection of the electronic component 102 and the electrical connection members coupled to the electronic component during assembly, as well as during operation/use, wherein the electronic component 102 and the electrical connection members may be subject to varying environment conditions (e.g., adverse operating conditions and assembly processes). As a non-limiting example, the epoxy resin may comprise a Bisphenol A-based epoxy resin. In various embodiments, the second cured epoxy material may comprise an epoxy having a color that is dark (e.g., black, tan, and/or the like) and which may absorb any incident light thereon. Examples of such epoxy include EP1325, EP1325LV, EP1320, EP1320LV, EN525.

Additionally and/or alternatively, the third layer 108c of the multi-layered protective coating may be formed at least in part of an epoxy resin having suitable curing properties (e.g., low viscosity, low curing time, and/or the like). In various embodiments, the third layer 108c is formed at least in part of a low viscosity epoxy resin, wherein the low viscosity epoxy resin may provide flow properties and/or depositing (e.g., dispensing) properties that enable the epoxy resin (and thus the multi-layered protective coating 108) to be evenly and efficiently deposited over relative to the electronic components and the electrical connection members. In various embodiments, the flow properties and/or depositing properties allows for dispensing of the epoxy resin over components in areas that that would otherwise be difficult (or impossible) to reach, such as electronic components located and electrical connection members located in difficult-to-reach areas of complex and/or intricate design circuits/component assembly.

In various embodiments, a second epoxy resin (e.g., as described above) may be cured using ultraviolet (UV) light/radiation to form the third layer 108c comprising a second cured epoxy layer. For example, the third layer 108c may be formed of a UV-cured epoxy resin, wherein the UV-cured epoxy resin may have low viscosity that provides suitable flow and/or depositing properties. In various embodiments, the third layer 108c may be formed at least in part of two or more epoxy resins having different properties so as to form a third layer 108c comprising a second cured epoxy material having a desired level of protection with respect to an electronic component and/or electrical connection members. In some embodiments the second cured epoxy material may comprise a silicon-based epoxy. For example, in various embodiments the second cured epoxy layer may comprise a silicon-based epoxy material. In some embodiments, the third layer 108c may comprise an epoxy having a viscosity between 36,000 cP and 400,000 cP. In some embodiments, the third layer 108c may have a color that is substantially black. In some embodiments, the third layer 108c may have a color that is substantially tan. In some embodiments, the third layer 108c may have a high ionic purity (e.g., Cl<50 ppm, K<50 ppm, Na<50 ppm). In some embodiments, the third layer 108c may have a Glass Transition Temperature (Tg) between 80 and 135° C.

In some embodiments, the first layer 108a and the third layer 108c of the multi-layered protective coating 108 may comprise the same material. For example, the first cured epoxy material may be the same as the second cured epoxy material. In some embodiments, the first layer 108a and the third layer 108c of the multi-layered protective coating may comprise different materials. For example, in some embodiments, the second cured epoxy material may be different from the second cured epoxy material.

In various embodiments, the multi-layered protective coating 108 may be configured to withstand a temperature of at least 100° C. In various embodiments, the multi-layered protective coating 108 may be configured to withstand a temperature of at least between 100° C. to 260° C.

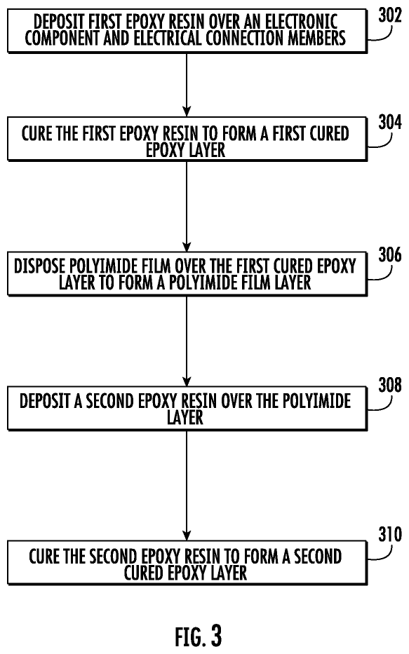

FIG. 3 provides an example flow chart 300 illustrating an exemplary method for forming a multi-layered protective coating on an electronic component (such as exemplary electronic components described above). In various embodiments, the process/operation that is depicted in FIG. 3 begins at step/operation 302 when a first epoxy resin (such as the epoxy resin described above) is deposited over an electronic component and electrical connection members coupled to the electronic component. In various embodiments, depositing the first epoxy resin over an electronic component and electrical connection members coupled to the electronic component may comprise weighing an amount of the first epoxy resin, wherein the amount of the first epoxy resin may be selected based at least in part on a desired thickness of a first layer of the multi-layered protective coating. In some embodiments, the first epoxy resin may comprise a single type of epoxy resin. In some embodiments, the first epoxy resin may comprise a combination of two or more epoxy resins of different types, wherein the two or more types of epoxy resins may be selected to produce a first epoxy resin having desired properties (e.g., desired mechanical properties, thermal properties, process properties, viscosity, and/or the like).

In various embodiments, the first epoxy resin may be deposited on the electronic component and the electrical connection members, such that the first epoxy resin covers the electronic component and the electrical connection members. In various embodiments, the electronic component may be mounted on a substrate (e.g., PCB) and a suitable amount of the first epoxy resin may be deposited over/on the electronic component, such that the first epoxy resin covers the electronic component and the electrical connection members, and such that the epoxy resin is in contact with the substrate around a perimeter defined by the electronic component and the electrical connection members. For example, in some embodiments, the first epoxy resin may be deposited on the electronic component and the electrical connection members, such that the first epoxy resin may be in contact with at least a portion of the substrate. In various embodiments, the first epoxy resin may have flow properties and/or dispensing properties that enable dispensing/depositing of the first epoxy resin on the electronic component and the electrical connection members, such that the first epoxy resin covers (e.g., at least substantially covers) the electronic component and the electrical connection members coupled to the electronic component.

In an example embodiment, the first epoxy resin may be combined (e.g., mixed) with one or more other materials. In the noted example embodiment, step/operation 302 may comprise depositing a composition comprising a first epoxy resin and one or more other materials on the electronic component and/or the one or more electrical connection members.

At step/operation 304, the first epoxy resin deposited on the electronic component and the electrical connection members is cured to form a cured epoxy layer, wherein the cured epoxy layer comprises a first layer of the multi-layered protective coating formed on the electronic component and the electrical connection members. In various the first layer of the multi-layered protective coating comprises a UV cured epoxy layer. For example, in various embodiments, curing the epoxy resin deposited on the electronic component and the electrical connection members may comprise applying UV light/radiation to the first epoxy resin deposited on the electronic component and the electrical connection members, wherein applying the UV light radiation facilitates curing (e.g., hardening) of the first epoxy resin over the electronic component and electrical connection members.

In various embodiments, curing the first epoxy resin deposited on the electronic component and the electrical connection members as described above results in a cured epoxy layer that encapsulates (e.g., encloses) the electronic component and the electrical connection members. In some embodiments, the first epoxy resin may be cured using a UV lamp, wherein the UV lamp may be caused to emit UV light/radiation towards the first epoxy resin so as to cure the epoxy resin while deposited on the electronic component and the electrical connection members. It should be understood, however, that the first epoxy resin may be UV cured utilizing a variety of devices and/or equipment configured for emitting UV light/radiation.

Additionally and/or alternatively, in some embodiments, the first epoxy layer deposited on the electronic component and the electrical connection members may be cured based at least in part on one or more thermal curing techniques, chemical curing techniques, and/or other curing techniques. In some embodiments, curing the first epoxy resin by applying UV light/radiation may produce a cured epoxy layer having a high strength, low viscosity, and high temperature resistance. Additionally, in some embodiments, curing the first epoxy resin utilizing UV curing technique (e.g., applying UV light/radiation to the first epoxy resin) may advantageously produce a first epoxy layer (e.g., first layer of the multi-layered protective coating) having a lower shrinkage (e.g., 1-2%) and/or higher heat resistance relative to at least some other curing techniques.

At step/operation 306, a polyimide film is disposed over the first cured epoxy layer to form a second layer (e.g., polyimide layer) of the multi-layered protective coating, wherein the polyimide film possesses at least one or more of mechanical properties, thermal properties, or optical properties that enable protection of the electronic component, such that the electronic component and the electrical connection members may be used in adverse conditions. For example, based at least in part on the polyimide film, the multi-layered protective coating may protect the electronic component and the electrical connection members against mechanical shock and thermal shock (e.g., that may be produced during assembly), as well as provide resistance to light/radiation, such that the performance of the electronic component and the electrical connection members are not adversely affected due to changing light conditions (e.g., changing ambient light conditions).

In various embodiments, the polyimide film encapsulates the first cured epoxy layer (thus, encapsulates the electronic component and the electrical connection members encapsulated by the first cured epoxy layer). In various embodiments, the polyimide film has a shape that enables disposing the polyimide film on the first cured epoxy layer in a manner that the polyimide film encapsulates the first cured epoxy layer. For example, in some, embodiments, disposing a polyimide film on the first cured epoxy layer may comprise forming a polyimide film in a shape that is substantially the same as the shape defined by the electronic component and the electrical connection members. In some embodiments, disposing a polyimide film on the first cured epoxy layer may comprise selecting a polyimide film having a shape that is substantially the same as the shape defined by the electronic component and the electrical connection members.

At step/operation 308, a second epoxy resin is deposited over the polyimide film (e.g., on top of the polyimide film). In various embodiments, depositing the second epoxy resin on the polyimide film may comprise weighing an amount of the second epoxy resin, wherein the amount of the second epoxy resin may be selected based at least in part on a desired thickness of a third layer of the multi-layered protective coating. In some embodiments, the second epoxy resin may comprise a single type of epoxy resin. In some embodiments, the second epoxy resin may comprise a combination of two or more epoxy resins of different types, wherein the two or more epoxy resins may be selected to produce a second epoxy resin having desired properties (e.g., desired mechanical properties, thermal properties, process properties, viscosity, and/or the like).

In various embodiments, the second epoxy resin may be deposited on the polyimide film (e.g., polyimide layer) such that the second epoxy resin covers the polyimide film (thus, covers the electronic component and the electrical connection member). For example, in various embodiments, a suitable amount of the second epoxy resin may be deposited over the polyimide film, such that the second epoxy resin covers the polyimide film, and such that the second epoxy resin is in contact with the substrate around a perimeter defined by the electronic component and the electrical connection members. In various embodiments, the second epoxy resin may have flow properties and/or dispensing properties that enable dispensing/depositing of the first epoxy resin on the polyimide film, such that the second epoxy resin covers (e.g., at least substantially covers) the polyimide film.

In an example embodiment, the second epoxy resin may be combined (e.g., mixed) with one or more other materials. In the noted example embodiment, step/operation 308 may comprise depositing a composition comprising a second epoxy resin and one or more other materials over the polyimide film. In various embodiments, the first epoxy resin and the second epoxy resin may be the same (e.g., having the same properties). In some embodiments, the first epoxy resin and the second epoxy resin may be different (e.g., having different properties).

At step/operation 310, the second epoxy resin deposited on the polyimide film is cured to form a second cured epoxy layer, wherein the second cured epoxy layer comprises a third layer of the multi-layered protective coating formed on the electronic component and the electrical connection members. In various embodiments, the third layer of the multi-layered protective coating comprises a UV cured epoxy layer. For example, in various embodiments, curing the second epoxy resin deposited on the electronic component and the electrical connection members may comprise applying UV light/radiation to the second epoxy resin deposited on the polyimide film, wherein applying the UV light radiation facilitates curing (e.g., hardening) of the second epoxy resin over the polyimide film. In various embodiments, curing the second epoxy resin deposited on the polyimide film as described above may result in a second cured epoxy layer that encapsulates (e.g., encloses) the polyimide film (and thus encapsulates the electronic component and the electrical connection members). In some embodiments, the second epoxy resin may be cured using a UV lamp, wherein the UV lamp may be caused to emit UV light/radiation towards the second epoxy resin so as to cure the second epoxy resin while deposited on the polyimide film. It should be understood, however, that the second epoxy resin may be UV cured utilizing a variety of devices and/or equipment configured for emitting UV light/radiation. Additionally and/or alternatively, in some embodiments, the second epoxy layer deposited on the polyimide film may be cured based at least in part on one or more thermal curing techniques, chemical curing techniques, and/or other curing techniques. In some embodiments, curing the second epoxy resin by applying UV light/radiation may produce a second cured epoxy layer having a high strength, low viscosity, and high temperature resistance. Additionally, in some embodiments, curing the second epoxy resin utilizing UV curing technique (e.g., applying UV light/radiation to the second epoxy resin) may advantageously produce a second epoxy layer (e.g., first layer of the multi-layered protective coating) having a lower shrinkage (e.g., 1-2%) and/or higher heat resistance relative to at least some other curing techniques.

Many modifications and other embodiments will come to mind to one skilled in the art to which this disclosure pertains having the benefit of the teachings presented in the foregoing descriptions and the associated drawings. Therefore, it is to be understood that the disclosure is not to be limited to the specific embodiments disclosed and that modifications and other embodiments are intended to be included within the scope of the appended claims. Although specific terms are employed herein, they are used in a generic and descriptive sense only and not for purposes of limitation.

1. A method for protecting an electronic component, the method comprising:
depositing a first epoxy resin on the electronic component;
curing the first epoxy resin to form a first cured epoxy layer;
disposing a polyimide film on the first cured epoxy layer to form a polyimide layer;
depositing a second epoxy resin on the polyimide layer; and
curing the second epoxy resin to form a second cured epoxy layer,
wherein the first cured epoxy layer, the polyimide layer, and the second epoxy layer form a multi-layered protective coating that is configured at least in part to protect the electronic component from at least adverse effects from varying light intensities.

2. The method of claim 1, wherein the multi-layered protective coating is further configured to protect the electronic component from mechanical shock.

3. The method of claim 1, wherein the multi-layered protective coating is further configured to protect the electronic component from thermal shock.

4. The method of claim 1, wherein the first cured epoxy layer comprises a first layer of the multi-layered protective coating, the polyimide layer comprises a second layer of the multi-layered protective coating, and the second epoxy resin comprises a third layer of the multi-layered protective coating.

5. The method of claim 1, wherein the multi-layered protective coating encapsulates the electronic component.

6. The method of claim 1, wherein the electronic component comprises a sensor.

7. The method of claim 1, wherein curing the first epoxy resin comprises applying ultraviolet (UV) light to the first epoxy resin.

8. The method of claim 1, wherein curing the second epoxy resin comprises applying ultraviolet (UV) light to the second epoxy resin.

9. The method of claim 1, wherein the polyimide film has a thickness of about 0.03 mm.

10. The method of claim 1, wherein the first epoxy resin has a low viscosity.

11. The method of claim 1, wherein the second epoxy resin has a low viscosity.

12. The method of claim 1, wherein the electronic component is coupled to one or more electrical connection members, and wherein the first epoxy resin is deposited on the electronic components and the electrical connection members.

13. The method of claim 12, further comprising, prior to disposing the polyimide film on the first cured epoxy layer, forming the polyimide film into a shape that is substantially the same as a shape defined by the electronic component and the electrical connection members coupled to the electronic component.

14. The method of claim 1, wherein the electronic component is disposed on a substrate, and wherein the first cured epoxy layer is in contact with at least a portion of the substrate.

15. The method of claim 1, wherein the first cured epoxy layer comprises a silicon-based epoxy material.

16. The method of claim 1, wherein the second cured epoxy layer comprises a silicon-based epoxy material.

17. An electronic component comprising:
one or more electrical connection members extending from the electronic component; and
a multi-layered protective coating formed on the electronic component and the one or more electrical connection members,
wherein the multi-layered protective coating is configured at least in part to protect the electronic component and the one or more electrical connection members from at least adverse effects from varying light intensities, and
wherein the multi-layered protective coating comprises a polyimide film disposed between a first epoxy layer and a second epoxy layer.

18. The electronic component of claim 17, wherein the multi-layered protective coating is further configured to protect the electronic component from mechanical shock.

19. The electronic component of claim 17, wherein the multi-layered protective coating is further configured to protect the electronic component from thermal shock.

20. The electronic component of claim 17, wherein the electronic component is a sensor.
